(19) United States
(12) Patent Application Publication
(10) Pub. No.: US 2026/0057912 A1
(43) Pub. Date: Feb. 26, 2026

(54) STACKED DRAM CELL AND STACKED DRAM CELL ARRAY USING SIDE RECESS PROCESS, AND MANUFACTURING METHOD OF STACKED DRAM CELL

(71) Applicant: POSTECH RESEARCH AND BUSINESS DEVELOPMENT FOUNDATION, Pohang-si (KR)

(72) Inventors: Sung-Woong CHUNG, Pohang-si (KR); Hyun June PARK, Pohang-si (KR); Min Su CHO, Pohang-si (KR); Sung Yun CHOI, Pohang-si (KR)

(21) Appl. No.: 19/098,196

(22) Filed: Apr. 2, 2025

(30) Foreign Application Priority Data
Aug. 21, 2024 (KR) 10-2024-0111871

(51) Int. Cl. G11C 5/06; G11C 11/4096

(52) U.S. Cl. CPC G11C 5/063; G11C 11/4096

(57) ABSTRACT

Provided is a stacked DRAM cell having a structure that includes two transistors, capable of being electrically connected to three signal lines, and effective for multi-layer stacking using a side recess process. The stacked DRAM cell has a write transistor and a dual-gate read transistor that includes a cut-off gate and a main gate, and has a structure in which a layer where a source line is formed, a layer where a cut-off gate channel is formed, a layer where a cut-off gate oxide layer is formed, a layer where a main gate channel is formed, a layer where a main gate oxide layer is formed, a layer where a storage node is formed, a layer where a write transistor channel is formed, a layer where a write transistor oxide layer is formed, and a layer where a write word line is formed are sequentially stacked.

### CROSS-REFERENCE TO RELATED APPLICATION

The present application claims priority of Korean Patent Application No. 10-2024-0111871 filed on Aug. 21, 2024, the entire contents of which are incorporated herein for all purposes by this reference.

### BACKGROUND OF THE DISCLOSURE

### Field of the Disclosure

The present disclosure relates to a stacked DRAM cell, and more particularly, to a stacked DRAM cell having a structure that includes two transistors, capable of being electrically connected to three signal lines, and effective for multi-layer stacking using a side recess process, a stacked DRAM cell array including multiple stacked DRAM cells, and a manufacturing method of a stacked DRAM cell.

### Description of the Related Art

The existing 1T1C cell (DRAM cell), which includes a single transistor (T) and a single capacitor (C), is currently widely used as a main memory in computers due to the fast operation speed and high integration density thereof. However, as the 1T1C DRAM cell continues to be miniaturized to improve integration density, the leakage level of the charge stored in the DRAM cell increases, and the difficulty in manufacturing capacitors with high integration density and capacitance also rises rapidly, leading to challenges in the miniaturization process.

Recently, to overcome these limitations of 1T1C DRAM cell, 2T0C DRAM cell including only two transistors (2T) and no capacitors (0C), using oxide semiconductor transistors such as InGaZnO (IGZO), which are widely used in display technology, have gained attention. The bandgap voltage of IGZO (3.2 eV) is approximately three times larger than that of Si (1.12 eV), and IGZO exhibits a very large asymmetric mobility between electrons and holes. As a result, the leakage current of IGZO is much lower than the leakage current of Si. Accordingly, it is possible to maintain the storage state of the charge corresponding to the information for a certain period of time in the 2T0C DRAM cell. It is also widely known that IGZO 2T0C DRAM cells have at least several hours of data retention time.

FIGS. 1A and 1B show a conventional 2T0C DRAM cell array circuit and a vertical structure of a 2T0C DRAM cell.

FIG. 1A shows an example of a 2T0C DRAM cell array 100 (hereinafter referred to as the conventional DRAM cell array) including two 2T0C DRAM cells (hereinafter referred to as conventional DRAM cells, Cell-1 and Cell-2). FIG. 1B shows a vertical cross-sectional view of the conventional DRAM cell array.

The conventional DRAM cell array includes four input/output lines WWL, WBL, RWL, RBL. Therefore, stacking DRAM cells has the disadvantage of increasing the height of the DRAM cell array.

### SUMMARY OF THE DISCLOSURE

An object of the present disclosure is to provide a stacked DRAM cell having a structure that includes two transistors, capable of being electrically connected to three signal lines, and effective for multi-layer stacking using a side recess process.

Another object of the present disclosure is to provide a stacked DRAM cell array, which includes multiple stacked DRAM cells having a structure that includes two transistors, capable of being electrically connected to three signal lines, and effective for multi-layer stacking using a side recess process.

Yet another object of the present disclosure is to provide a manufacturing method of a stacked DRAM cell having a structure that includes two transistors, capable of being electrically connected to three signal lines, and effective for multi-layer stacking using a side recess process.

The technical objects disclosed in the present disclosure are not limited to the aforementioned technical objects, and unmentioned other technical objects will be clearly appreciated by those skilled in the art from the following description.

A stacked DRAM cell according to an embodiment of the present disclosure, aimed at achieving the technical object, includes a write transistor and a dual-gate read transistor. A cut-off gate of the dual gate is electrically connected to a source line formed on an upper portion of a first isolation layer. A main gate of the dual gate is insulated from a storage node by an oxide layer formed on an upper portion of the main gate and is electrically connected to a bit line formed in a vertical direction to a layer containing the main gate. A gate of the write transistor forms a word line, a channel of the write transistor is formed on an upper portion of the storage node, and one terminal of the write transistor is electrically connected to the bit line.

A stacked DRAM cell array according to one aspect of the present disclosure, aimed at achieving another technical object, includes a DRAM cell, which includes a write transistor and a dual-gate read transistor, configured to be sequentially stacked. A cut-off gate of the dual gate is electrically connected to a source line formed on an upper portion of a first isolation layer. A main gate of the dual gate is insulated from a storage node by an oxide layer formed on an upper portion of the main gate and is electrically connected to a bit line formed in a vertical direction to a layer containing the main gate. A gate of the write transistor forms a word line, a channel of the write transistor is formed on an upper portion of the storage node, and one terminal of the write transistor is electrically connected to the bit line.

A stacked DRAM cell array according to another aspect of the present disclosure, aimed at achieving another technical object, includes a DRAM unit cell, which includes a write transistor and a dual-gate read transistor and is arranged in a three-dimensional configuration. The DRAM unit cell has a structure in which a layer where a source line is formed, a layer where a cut-off gate channel is formed, a layer where a cut-off gate oxide layer is formed, a layer where a main gate channel is formed, a layer where a main gate oxide layer is formed, a layer where a storage node is formed, a layer where a write transistor channel is formed, a layer where a write transistor oxide layer is formed, and a layer where a write word line is formed are sequentially stacked.

A manufacturing method of a stacked DRAM cell according to an embodiment of the present disclosure, aimed at achieving yet another technical object, includes stacking multiple functional layers to manufacture a DRAM cell including a write transistor and a dual-gate read transistor, forming a first isolation region and a second isolation region by etching all the stacked multiple functional layers at regular intervals, etching some layers within the multiple functional layers to form a word line and a source line, forming a cut-off gate by etching some layers above the source line within the multiple functional layers, forming a storage node by etching some layers above the cut-off gate within the multiple functional layers, and forming a bit line by vertically etching all the multiple functional layers.

The technical objects disclosed in the present disclosure are not limited to the aforementioned technical objects, and unmentioned other technical objects will be clearly appreciated by those skilled in the art from the following description.

As described above, the stacked DRAM cell and stacked DRAM cell array using the side recess process, and the manufacturing method of a stacked DRAM cell according to the embodiment of the present disclosure have the advantage in that the gate of the read transistor, one of the two transistors, is configured as a dual gate including the main gate and the cut-off gate. Additionally, the operation of the unselected cell during the read operation may be blocked by connecting the cut-off gate terminal to the source line, and multi-layer DRAM cells may be easily manufactured using the side recess method.

As described above, the structure and manufacturing method of the stacked DRAM cell using the side recess process according to the present disclosure have the advantage of reducing the area occupied by the DRAM cell array by allowing adjacent DRAM unit cells to share the source line contact. The effects of the present disclosure are not limited to those mentioned above. Other unmentioned effects will be clearly understood by those skilled in the art from the description below.

### BRIEF DESCRIPTION OF THE DRAWINGS

FIGS. 1A and 1B show a conventional 2T0C DRAM cell array circuit and a vertical structure of a 2T0C DRAM cell.

FIGS. 2A and 2B show an example of a stacked DRAM cell array and a vertical structure of a stacked DRAM cell according to the present disclosure.

FIG. 3 shows an embodiment of a manufacturing method of a stacked DRAM cell array according to the present disclosure.

FIG. 4 shows another embodiment of a manufacturing method of a stacked DRAM cell array according to the present disclosure.

FIG. 5 shows a stacked state of multiple functional layers of a stacked DRAM cell.

FIG. 6 shows the state after performing a step of forming a first isolation region by etching the stacked layers in a single direction.

FIG. 7 shows the state after performing a step of filling the first isolation region with an insulating material.

FIG. 8 shows the state after performing a step of forming a second isolation region by etching the stacked layers filled with an insulating material in a direction perpendicular to the single direction.

FIG. 9 shows the state after performing a step of defining word line and source line regions.

FIG. 10 shows the state in which a portion of a second isolation layer is virtually removed.

FIG. 11 shows the state after performing a step of depositing a conductive material in the defined regions.

FIG. 12 shows the state after etching a layer where a channel of a cut-off gate is to be formed.

FIG. 13 shows the state after performing a step of depositing a conductive material in the defined channel region of the cut-off gate.

FIG. 14 shows the state after performing the step of depositing an insulating material on both sides of the conductive material.

FIG. 15 shows the state after performing the step of etching a portion of the layer where a storage node is to be formed to define a space for the storage node.

FIG. 16 shows the state after depositing a conductive material into the space defined as the storage node and etching a portion of the area.

FIG. 17 shows the state after performing a step of filling a vertical via hole with a conductive material to form a vertical bit line.

FIG. 18 shows the state after performing a step of connecting terminals of the vertical bit line to the horizontal bit line oriented in a horizontal direction.

FIG. 19 shows the state after performing a step of forming the storage node shown in FIG. 4.

FIG. 20 shows the state after performing a step of forming the cut-off gate shown in FIG. 4.

FIGS. 21A and 21B show a side cross-sectional view of the stacked DRAM cell according to the present disclosure.

FIGS. 22A and 22B show another embodiment of forming a word line and a source line.

FIG. 23 is an embodiment that shows the process of forming a storage node in detail.

### DETAILED DESCRIPTION OF THE DISCLOSURE

In order to sufficiently understand the present disclosure, advantages in operation of the present disclosure, and the object to be achieved by carrying out the present disclosure, reference needs to be made to the accompanying drawings for illustrating an embodiment of the present disclosure and contents disclosed in the accompanying drawings.

Hereinafter, the present disclosure will be described in detail through description of preferred embodiments of the present disclosure with reference to the accompanying drawings. Like reference numerals indicated in the respective drawings refer to like members.

The present disclosure relates to a DRAM unit cell including two transistors, a DRAM cell array formed by stacking multiple DRAM unit cells, and a manufacturing method of a DRAM cell. Reflecting the features of the configuration and manufacturing method of the present disclosure, the following descriptions will refer to a DRAM unit cell, a stacked DRAM cell, and a stacked DRAM cell array.

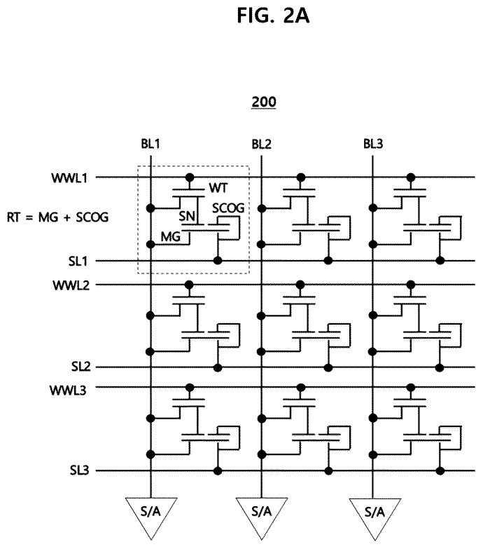

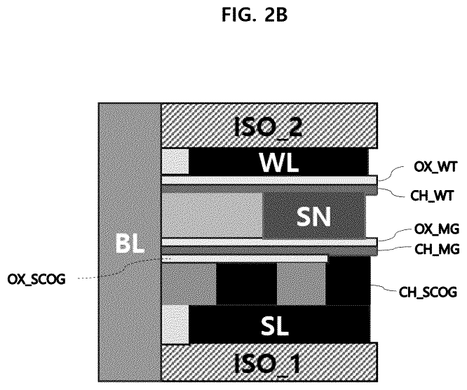

FIGS. 2A and 2B show an example of a stacked DRAM cell array and a vertical structure of a stacked DRAM cell according to the present disclosure.

Referring to FIG. 2A, a stacked DRAM cell array 200 according to the present disclosure includes multiple stacked DRAM cells, with each stacked DRAM cell within the dotted rectangle at the upper left of FIG. 2A, serving as a unit. It may be seen that each stacked DRAM cell includes a single write transistor (WT) and a single read transistor (RT).

For convenience of description, the configuration of the stacked DRAM cell within the dotted rectangle will be described, and this configuration will then be applied to other stacked DRAM cells.

The write transistor (WT) has one terminal connected to a bit line BL1, a gate terminal connected to the write word line WWL1 (hereinafter referred to as the word line), and the other terminal connected to a storage node (SN).

The read transistor (RT) includes two gate terminals: a main gate (MG) terminal and a sneak current off gate (SCOG) terminal (hereinafter referred to as the cut-off gate). One terminal is connected to the bit line BL1, and the other terminal is connected to a source line SL1. The main gate (MG) terminal is shared with one terminal of the write transistor (WT) and is also used for the storage node (SN). The cut-off gate (SCOG) terminal is connected to both the other terminal and the source line SL1.

As described above, since the read transistor (RT) includes two gate terminals, the following description will use the terms ‘read transistor (RT)’ and ‘dual-gate transistor’ interchangeably. The main gate (MG) and the cut-off gate (SCOG) will also be used interchangeably to refer to the main gate (MG) terminal and the cut-off gate (SCOG) terminal, respectively.

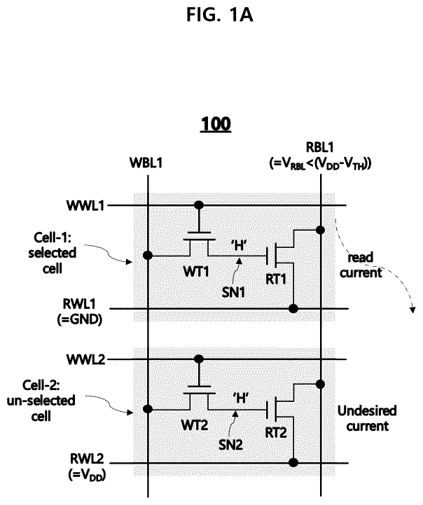

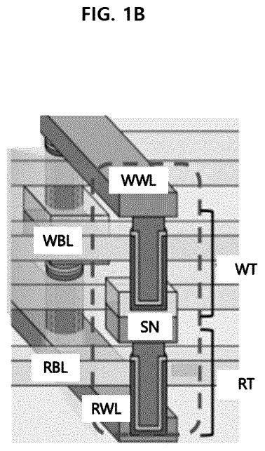

The stacked DRAM cell array 200 according to the present disclosure shown in FIG. 2A and a conventional DRAM cell array 100 shown in FIGS. 1A and 1B have the following differences.

The read transistor (RT) of the conventional DRAM cell 100 has a single gate, whereas the read transistor (RT) of the stacked DRAM cell provided in the present disclosure has two gates, which is a difference. The two gates include the main gate (MG) and the cut-off gate (SCOG). For convenience of description, the two gates will also be referred to as a dual gate.

The main gate (MG) terminal of the present disclosure is shared with one terminal of the write transistor (WT) and is also used for the storage node (SN), and the cut-off gate (SCOG) terminal is connected to a source line (SL). This differs from the function and connection relationships of the conventional read transistor (RT).

Finally, the conventional DRAM cell shown in FIG. 1A requires four terminals connected to four signal lines WWL, WBL, RWL, RBL, whereas the stacked DRAM cell according to the present disclosure, shown in FIG. 2A, requires only three terminals connected to three signal lines WWL, BL, SL, which is another difference.

Referring to FIG. 2B, the vertical structure of the stacked DRAM cell according to the present disclosure includes stacked multiple functional layers, with the stacked functional layers being electrically isolated from the outside or other layers by two isolation layers ISO_1 and ISO_2 formed at the lowermost and topmost layers.

A layer (SL) where the source line (SL) is formed, located on top of the lowermost first isolation layer ISO_1, a layer where a cut-off gate channel CH_SCOG is formed, a layer where a cut-off gate oxide layer OX_SCOG is formed, a layer where a main gate channel CH_MG is formed, and a layer where a main gate oxide layer OX_MG is formed, a layer (SN) where the storage node (SN) is formed, a layer where a write transistor channel CH_WT is formed, a layer where a write transistor oxide layer OX_WT is formed, a layer (WL) where a write word line WWL1 is formed, and a second isolation layer ISO_2 are stacked sequentially. Each of these stacked layers is a functional layer.

FIG. 2B illustrates the stacking order of each layer of the structure. The actual configuration and manufacturing method of the stacked DRAM cell will be described below.

A manufacturing method of a stacked DRAM cell array according to the present disclosure will be described below. The vertical structure of the stacked DRAM cell and the configuration of the stacked DRAM cell array will also be described during the description.

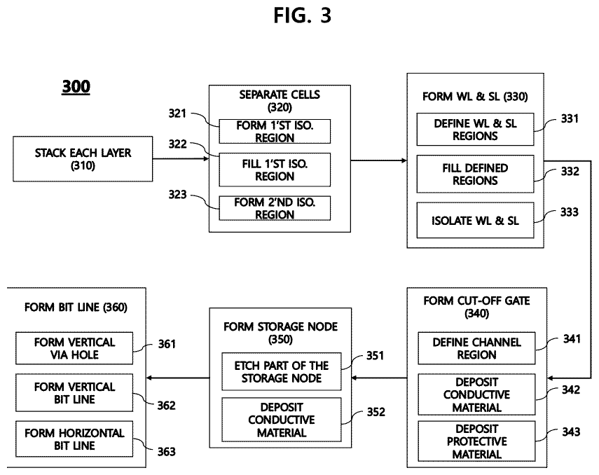

FIG. 3 shows an embodiment of a manufacturing method of a stacked DRAM cell array according to the present disclosure.

Referring to FIG. 3, a manufacturing method 300 of the stacked DRAM cell array according to the present disclosure includes a step 310 of stacking each layer, a step 320 of isolating cells, a step 330 of forming a word line and a source line, a step 340 of forming a cut-off gate, a step 350 of forming a storage node, and a step 360 of forming a bit line.

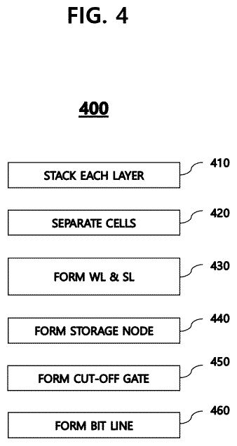

FIG. 4 shows another embodiment of a manufacturing method of a stacked DRAM cell array according to the present disclosure.

Referring to FIG. 4, a manufacturing method 400 of the stacked DRAM cell array according to the present disclosure includes a step 410 of stacking each layer, a step 420 of isolating cells, a step 430 of forming a word line and a source line, a step 440 of forming a storage node, a step 450 of forming a cut-off gate, and a step 460 of forming a bit line.

Comparing FIGS. 3 and 4, it may be seen that the step 340 and 450 of forming the cut-off gate and the step of 350 and 440 forming the storage node in the manufacturing method of the stacked DRAM cell array according to the present disclosure may be performed in reverse order.

First, the manufacturing method 300 shown in FIG. 3 will be described, and this method will then be applied to the manufacturing method 400 of the stacked DRAM cell array shown in FIG. 4.

In the step 310 of stacking, multiple functional layers of the stacked DRAM cell are stacked.

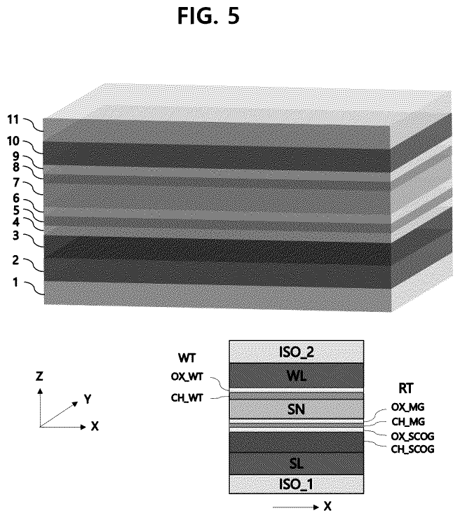

FIG. 5 shows a stacked state of multiple functional layers of a stacked DRAM cell.

The left side of FIG. 5 is a perspective view of a state in which multiple functional layers are stacked, and the right side is a side cross-sectional view of a state in which multiple functional layers are stacked.

Referring to FIG. 5, the stacked multiple functional layers include, from the bottom, a first isolation layer 1 (ISO_1), a layer 2 where the source line (SL) is to be formed, a layer 3 (CH_SCOG) where the cut-off gate channel is to be formed, a layer 4 (OX_SCOG) where the cut-off gate oxide layer is to be formed, a layer 5 (CH_MG) where the main gate channel is to be formed, a layer 6 (OX_MG) where the main gate oxide layer is to be formed, a layer 7 where the storage node is to be formed (SN), a layer 8 (CH_WT) where the write transistor channel is to be formed, a layer 9 (OX_WT) where the write transistor oxide layer is to be formed, a layer 10 (WL) where the write word line is to be formed, and a second isolation layer 11 (ISO_2).

The step 320 of isolating cells includes a step 321 of forming a first isolation region by etching the stacked layers in a single direction, a step 322 of filling the first isolation region with an insulating material, and a step 323 of forming a second isolation region by etching the stacked layers filled with the insulating material in a direction perpendicular to the single direction.

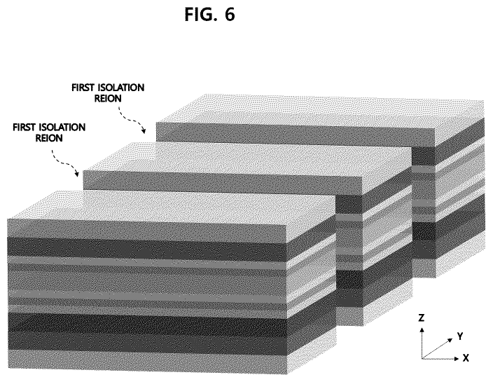

FIG. 6 shows the state after performing the step of forming the first isolation region by etching the stacked layers in a single direction.

FIG. 7 shows the state after performing the step of filling the first isolation region with an insulating material.

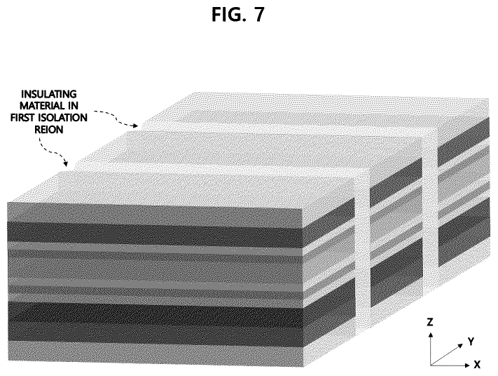

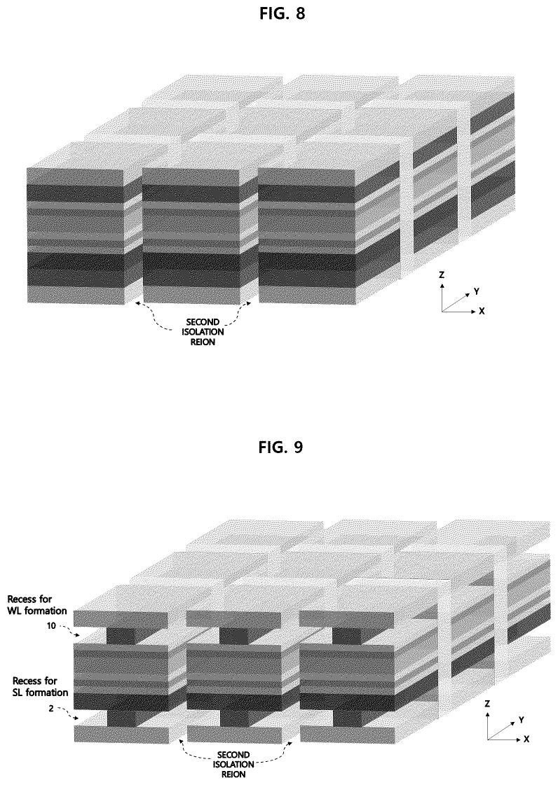

FIG. 8 shows the state after performing the step of etching in a direction perpendicular to the direction of the first isolation region to form the second isolation region.

The dashed arrows shown in FIGS. 6 to 8 indicate the first isolation region, the insulating material filled in the first isolation region, and the second isolation region, respectively.

The step 330 of forming a word line and a source line includes a step 331 of defining the word line and source line regions, a step 332 of depositing a conductive material in the regions defined as the word line and source line to form the word line and source line, and a step 333 of isolating the surface of the formed word line and source line from the outside.

The reason for isolating the surface of the word line and source line from the outside is to prevent the surface of the word line and source line from being affected by subsequent etching processes.

FIG. 9 shows the state after performing the step of defining the word line and source line regions.

Referring to FIG. 9, the step 331 of defining the word line and source line regions is performed by a side recess process through the empty second isolation region. The word line and source line regions are defined by primarily etching the layer 2 where the source line is to be formed and the layer 10 where the word line is to be formed. For reference, the recess process is a type of etching process commonly used in semiconductor manufacturing, which involves the use of plasma or chemical solutions to finely remove specific areas or adjust the depth or height of a formed pattern. In this case, it is preferred to use isotropic etching or wet etching techniques to ensure proper lateral recessing. In addition, it is preferred that the word line and source line are formed of the same type of conductive material, as this allows the recess process to be performed using the same etchant.

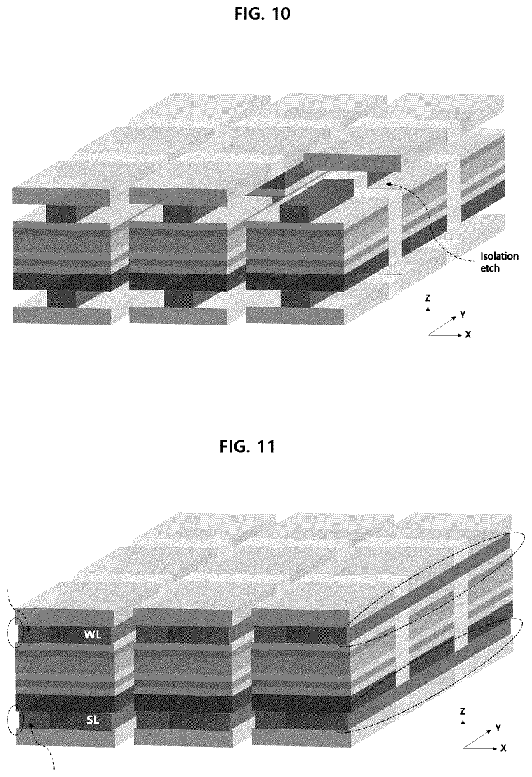

FIG. 10 shows the state in which a portion of the second isolation layer 11 is virtually removed solely to aid understanding of the structure of the present disclosure.

Referring to FIG. 10, it may be seen that the step 331 of defining the word line and source line regions may define the fully formed word line and source line regions by secondarily etching the fill material in the first isolation region of the same layer as the word line and source line. The etchant used in the secondary etching step may etch only the insulating material filled in the first isolation region. This process is labeled as “isolation etch” in FIG. 10.

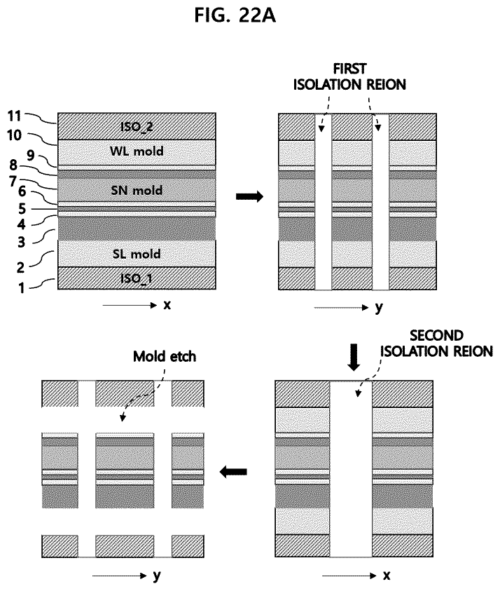

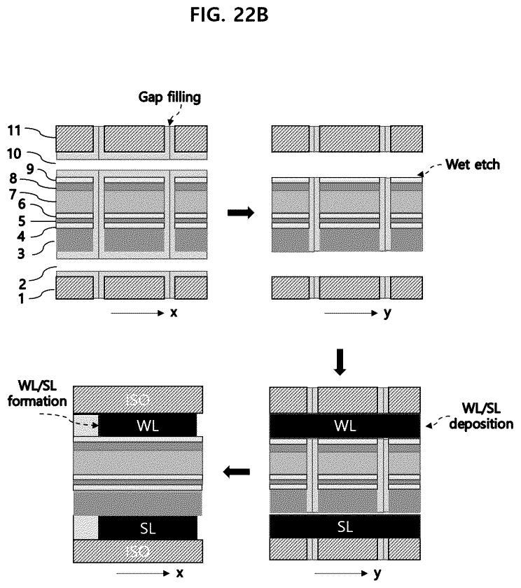

To make the word line and source line have the same structure as shown in FIG. 10, the manufacturing process may be conducted differently. Another embodiment is shown in FIGS. 22A and 22B, where the steps of the process are illustrated sequentially. Taking FIGS. 22A and 22B as examples, a material such as an Amorphous Carbon Layer (ACL) may be filled into the layer where the word line and source line are to be formed (in FIG. 22A, these are labeled as ‘WL_mold’ and ‘SL_mold,’ respectively), which may then be used as a hard mask. For reference, since each of FIGS. 22A and 22B represents a top view, it should be noted that directions such as ‘x’ or ‘y’ are indicated below to aid understanding.

Referring to FIG. 22A, after forming the first isolation region and second isolation region by etching, a process (mold etch) of removing the mold (WL_mold) is shown. Referring to FIG. 22B, a process is shown where an insulating material is deposited into each isolation region to fill the gaps (gap filling), a portion of the insulating material is removed by wet etching (wet-etch), the word line and source line materials are deposited (WL/SL deposition), portions of the word line and source line are removed, and the insulating material is refilled to complete the word line and source line structure (WL/SL formation).

FIG. 11 shows a three-dimensional view after performing the steps of FIG. 10 or FIGS. 22A and 22B.

Comparing FIGS. 10 and 11, it may be seen that the insulating material is deposited at the location indicated by the dashed arrow in FIG. 11.

The step 340 of forming a cut-off gate includes a step 341 of defining a channel region of the cut-off gate by etching the layer 3 where a channel of the cut-off gate is to be formed, a step 342 of depositing a conductive material in the defined channel region of the cut-off gate, and a step 343 of depositing a material to protect both sides of the conductive material.

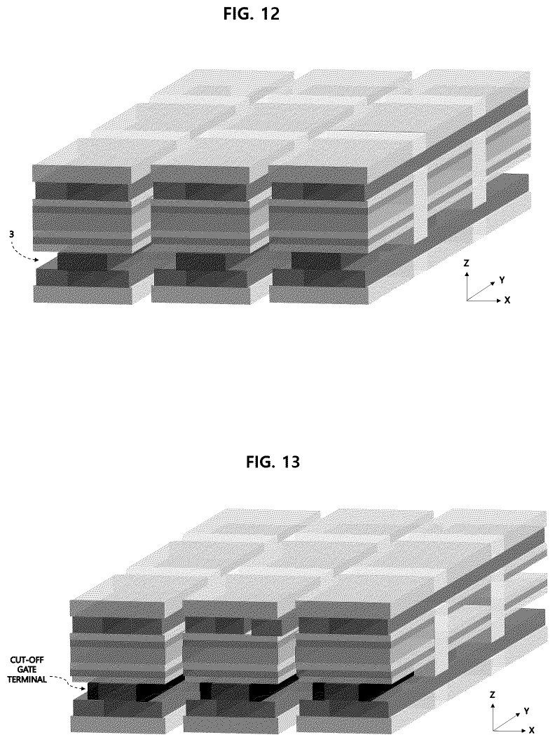

FIG. 12 shows the state after etching a layer where the channel of the cut-off gate is to be formed.

Referring to FIG. 12, the dashed arrows indicate the areas where the channel of the cut-off gate is to be formed.

FIG. 13 shows the state after performing the step of depositing a conductive material in the channel region of the cut-off gate.

FIG. 14 shows the state after performing the step of depositing an insulating material on both sides of the conductive material.

The step 350 of forming the storage node includes a step 351 of etching a portion of the layer 7 where the storage node is to be formed, and a step 352 of depositing a conductive material in the etched region. In the step 352 of depositing a conductive material in the etched region for the storage node, the conductive material may be simultaneously deposited to connect the layer 2 where the source line is to be formed to an end of the read transistor (RT), which serves as a source line contact (SLC).

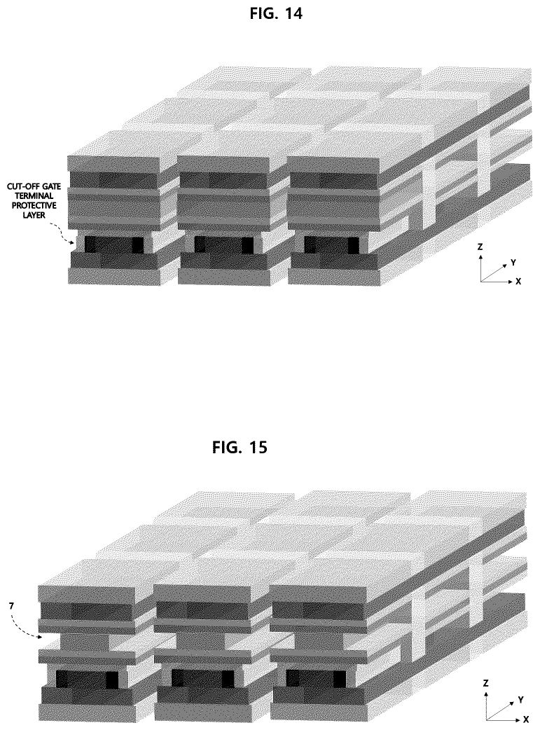

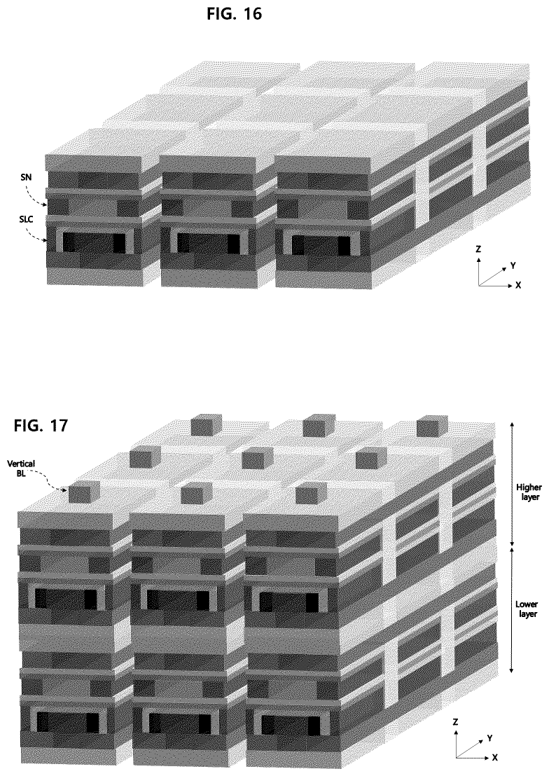

FIG. 15 shows the state after performing the step of etching a portion of the layer where the storage node is to be formed to define a space for the storage node.

Subsequently, a storage node material is deposited into this space.

FIG. 16 shows the state after depositing a conductive material into the space defined as the storage node and etching a portion of the area.

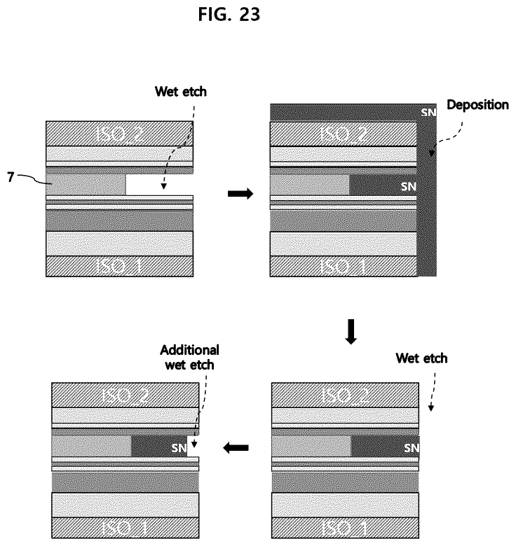

FIG. 23 shows an embodiment illustrating the sequential and detailed process for forming the storage node. Assuming that the layer 7 where the storage node is to be formed is, for example, a nitride layer, an etchant capable of etching the nitride layer is used to remove a portion of the nitride layer. In this case, it is preferred to use the wet etching technique to perform isotropic etching. The next step is to deposit the material that is to be the storage node. The material to be the storage node is preferably a conductive material. Next, after removing the vertically formed conductive material by wet etching, additional wet etching is performed to make the sides of the storage node concave.

It is considered important that a single source line contact (SLC) may not only be formed exclusively for one DRAM cell but also allow two adjacent DRAM cells to share a single source line contact (SLC), as this enables efficient use of semiconductor area. Such an embodiment is also possible and is described below.

The step 360 of forming a bit line includes a step 361 of forming a vertical via hole where a bit line is to be formed by etching in a vertical direction, a step 362 of filling the vertical via hole with a conductive material to form a vertical bit line (Vertical BL), and a step 363 of forming a horizontal bit line (Horizontal BL), oriented in a horizontal direction, to which terminals of the vertical bit line (Vertical BL) are connected.

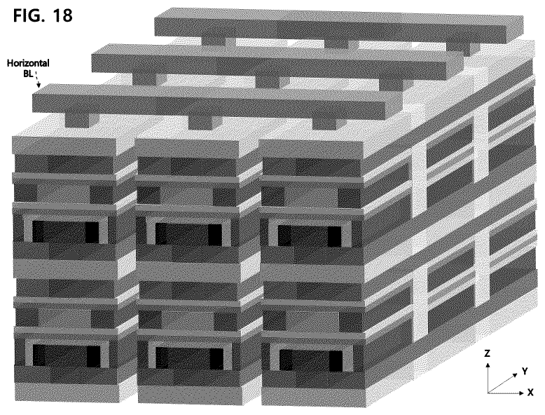

Depending on the embodiment, after performing the step 361 but before performing the step 362, a step of depositing a material with electrical properties similar to those of the channel to the via hole may be additionally performed. The conductive material filled in the bit line (BL) directly contacts the channel with the thin film thickness. Depending on the embodiment, an additional step may serve to increase the contact area between the bit line (BL) and the channel. FIG. 17 shows the state after performing the step of filling the vertical via hole with a conductive material to form a vertical bit line (Vertical BL).

The vertical via hole passes through the layer 3 where the cut-off gate channel is formed, the layer 4 where the cut-off gate oxide layer is formed, the layer 5 where the main gate channel is formed, the layer 6 where the main gate oxide layer is formed, the layer 7 where the storage node is formed, the layer 8 where the write transistor channel is formed, the layer 9 where the write transistor oxide layer is formed, the layer 10 where the write word line is formed, and the upper oxide layer 11, and the vertical bit line (Vertical BL) may be implemented by filling the vertical via hole with a conductive material.

FIGS. 5 to 16 describe multiple DRAM cells arranged in a two-dimensional configuration on a single layer to describe the structure of the stacked DRAM cell array 200. However, this is for convenience of description, and an embodiment having a three-dimensional structure by stacking at least two two-dimensional arrays of DRAM cells is also possible. In one of various embodiments, FIG. 17 illustrates the stacked DRAM cell array 200, shown as including two layers (a higher layer and a lower layer).

In addition, since a person skilled in the art of semiconductor manufacturing may understand the technique of performing the step 361 of forming a vertical via hole where a vertical bit line is to be formed by etching in a vertical direction, no drawing is included here and no separate description is provided.

FIG. 18 shows the state after performing a step of connecting terminals of the vertical bit line to the horizontal bit line oriented in a horizontal direction.

Referring to FIGS. 17 and 18, the vertical bit line and the horizontal bit line may take the form of a vertical bar and a horizontal bar, respectively.

In the above description, the layer where the second isolation layer ISO_2 is formed is described and shown as the topmost layer. However, depending on the embodiment, a layer where the horizontal bit line is formed may be additionally added.

The manufacturing method 300 of the stacked DRAM cell array shown in FIG. 3 and the manufacturing method 400 of the stacked DRAM cell array shown in FIG. 4 are the same, except for the order of the step of forming the cut-off gate and the step of forming the storage node. Therefore, the steps before and after these two steps (forming the cut-off gate and forming the storage node) are as described above.

Furthermore, since the embodiment shown in FIG. 3 has been described earlier, the following description will focus only on the structure of the DRAM cell array where the order of the steps is reversed.

For convenience of description, an example with a single second isolation region will be described.

FIG. 19 shows the state after performing the step of forming a storage node shown in FIG. 4.

Referring to FIG. 19, it may be seen that the step 440 of forming a storage node is performed in a state where a word line 10 and a source line 2 are formed, but the cut-off gate is not formed.

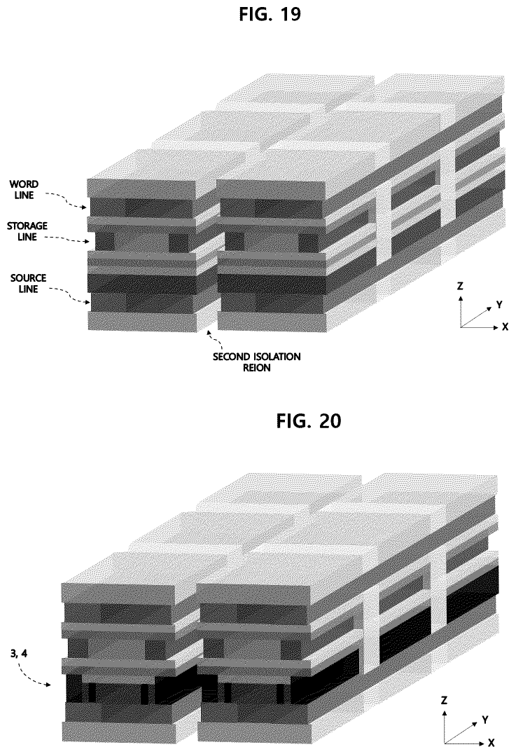

FIG. 20 shows the state after performing the step of forming a cut-off gate shown in FIG. 4.

Referring to FIG. 20, it may be seen that the step 450 of forming a cut-off gate is performed on the two layers 3 and 4 after the step 440 of forming a storage node, that is, after the storage node (SN) is formed in the layer 7 where the storage node is to be formed.

In the case of the stacked DRAM cell 200 according to the present disclosure, there is an advantage in that the layout and manufacturing process may be simplified by manufacturing two adjacent cells to share a single source line contact (SLC).

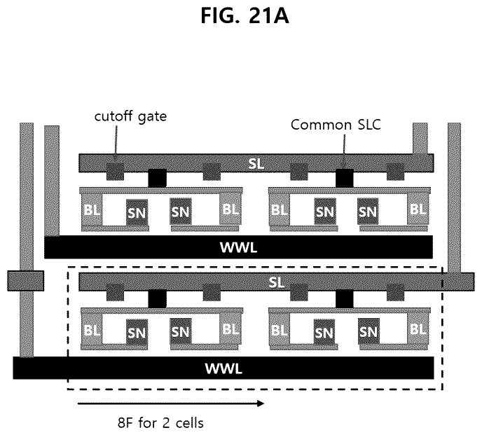

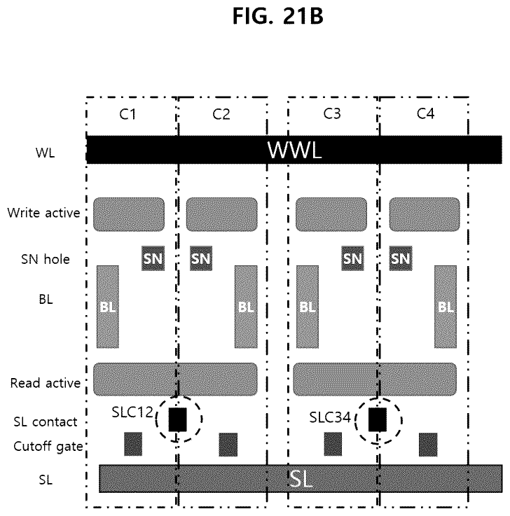

FIGS. 21A and 21B show a side cross-sectional view of the stacked DRAM cell according to the present disclosure.

FIG. 21A shows a stacked state of the stacked DRAM cells in two layers. FIG. 21B is an enlarged view of the dashed portion of FIG. 21A with the top and bottom inverted.

FIG. 21B shows a total of four DRAM cells C1 to C4, with two DRAM cells C1 and C2 sharing one source line contact SLC12 and the remaining two DRAM cells C3 and C4 sharing the other source line contact SLC34.

While the technical spirit of the present disclosure has been described above with reference to the accompanying drawings, this is only an example of a preferred embodiment of the present disclosure and does not limit the present disclosure. In addition, it is apparent that those skilled in the art to which the present disclosure pertains may variously modify and imitate the present disclosure without departing from the scope of the technical spirit of the present disclosure.

What is claimed is:

1. A stacked DRAM cell comprising:
a write transistor and a dual-gate read transistor, wherein a cut-off gate of the dual gate is electrically connected to a source line formed on an upper portion of a first isolation layer,
a main gate of the dual gate is insulated from a storage node by an oxide layer formed on an upper portion of the main gate and is electrically connected to a bit line formed in a vertical direction to a layer containing the main gate, and
a gate of the write transistor forms a word line, a channel of the write transistor is formed on an upper portion of the storage node, and one terminal of the write transistor is electrically connected to the bit line.

2. The stacked DRAM cell of claim 1, wherein a gate oxide layer is formed on an upper portion of the channel of the write transistor.

3. The stacked DRAM cell of claim 1, wherein a second isolation layer is formed on an upper portion of the word line.

4. The stacked DRAM cell of claim 1, wherein a capacitance component due to the oxide layer is at least a part of a capacitance component of the storage node.

5. A stacked DRAM cell array comprising:
a DRAM cell, which includes a write transistor and a dual-gate read transistor, configured to be sequentially stacked,
wherein a cut-off gate of the dual gate is electrically connected to a source line formed on an upper portion of a first isolation layer,
a main gate of the dual gate is insulated from a storage node by an oxide layer formed on an upper portion of the main gate and is electrically connected to a bit line formed in a vertical direction to a layer containing the main gate, and
a gate of the write transistor forms a word line, a channel of the write transistor is formed on an upper portion of the storage node, and one terminal of the write transistor is electrically connected to the bit line.

6. The stacked DRAM cell array of claim 5, wherein the DRAM cells are repeatedly arranged in a plane each perpendicular to the stacking direction.

7. The stacked DRAM cell array of claim 5, wherein the stacked DRAM cells are insulated from each other by the first isolation layer.

8. A stacked DRAM cell array comprising:
a DRAM unit cell, which includes a write transistor and a dual-gate read transistor and is arranged in a three-dimensional configuration,
wherein the DRAM unit cell has a structure in which a layer where a source line is formed, a layer where a cut-off gate channel is formed, a layer where a cut-off gate oxide layer is formed, a layer where a main gate channel is formed, a layer where a main gate oxide layer is formed, a layer where a storage node is formed, a layer where a write transistor channel is formed, a layer where a write transistor oxide layer is formed, and a layer where a write word line is formed are sequentially stacked.

9. The stacked DRAM cell array of claim 8, wherein an insulating material is partially filled in each layer where the source line, word line, and storage node are formed.

10. The stacked DRAM cell array of claim 8, wherein a bit line layer is embedded in a direction perpendicular to the sequentially stacked direction.

11. A manufacturing method of a stacked DRAM cell, the manufacturing method comprising:
stacking multiple functional layers to manufacture a DRAM cell including a write transistor and a dual-gate read transistor,
forming a first isolation region and a second isolation region by etching all the stacked multiple functional layers at regular intervals,
etching some layers within the multiple functional layers to form a word line and a source line,
forming a cut-off gate by etching some layers above the source line within the multiple functional layers,
forming a storage node by etching some layers above the cut-off gate within the multiple functional layers; and
forming a bit line by vertically etching all the multiple functional layers.

12. The manufacturing method of claim 11, wherein the etching of some layers within the multiple functional layers to form the word line and the source line involves a side recess.

13. The manufacturing method of claim 11, wherein the forming of the bit line further includes depositing material in the vertically etched areas.

14. The manufacturing method of claim 11, wherein an upper or lower portion of the multiple functional layers includes an insulating layer for insulating the DRAM cell from other DRAM cells.

15. The manufacturing method of claim 11, wherein the forming of the first isolation region and the second isolation region includes depositing an insulating material.

16. The manufacturing method of claim 11, further comprising forming a source line contact connecting the source line to an end of the read transistor.

17. The manufacturing method of claim 16, wherein the source line contact is shared by adjacent DRAM cells.

18. The manufacturing method of claim 11, wherein adjacent DRAM cells are isolated from each other by the first isolation region and the second isolation region.

19. The manufacturing method of claim 11, wherein the word line, the source line, the cut-off gate, and the storage node are formed on different layers.

20. The stacked DRAM cell array of claim 8, wherein the DRAM unit cell is electrically connected to an adjacent DRAM unit cell through the respective word line, source line, and bit line.
